(19) United States
(12) Patent Application Publication
(10) Pub. No.: US 2025/0357402 A1
(43) Pub. Date: Nov. 20, 2025

(54) METAL BUMP STRUCTURES AND METHODS OF FORMING THE SAME

(71) Applicant: Taiwan Semiconductor Manufacturing Company, Ltd., Hsin-Chu (TW)

(72) Inventors: Chang-Jung Hsueh, Taipei (TW); Chieh-Ning Feng, Taichung City (TW); Yu-Lun Liu, Tainan City (TW); Wen-Hsiung Lu, Hsinchu (TW); Ming-Da Cheng, Hsinchu (TW)

(21) Appl. No.: 19/288,712

(22) Filed: Aug. 1, 2025

Related U.S. Application Data
(63) Continuation of application No. 18/365,667, filed on Aug. 4, 2023.
(60) Provisional application No. 63/502,858, filed on May 17, 2023.

(51) Int. Cl. H01L 23/00

(52) U.S. Cl. CPC H01L 24/13; H01L 24/11; H01L 2224/11462; H01L 2224/11903; H01L 2224/11916; H01L 2224/13006; H01L 2224/13008; H01L 2224/13014; H01L 2224/13017; H01L 2224/13147; H01L 2924/01029; H01L 2924/35121

(57) ABSTRACT

Semiconductor structures and methods are provided. An exemplary semiconductor structure includes a contact pad over a substrate, an under-bump metallization (UBM) layer over the contact pad, a metal pillar over first UBM layer and electrically coupled to the contact pad via the UBM layer, and a solder cap on the metal pillar. The metal pillar comprises copper, and a percentage of (111) crystal orientation of the copper is 90% or more.

### PRIORITY

The present application is a continuation application of U.S. patent application Ser. No. 18/365,667, filed Aug. 4, 2023, which claims the benefit of U.S. Provisional Application No. 63/502,858 filed May 17, 2023, each of which is herein incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

For example, ICs are formed on a semiconductor substrate. An IC chip may be bonded to a package substrate via metal bumps. Copper pillar bumps are suitable for smaller bump pitches. However, for large die sizes prevalent in, for example, high-performance computing (HPC), the copper pillar bumps may induce high stress on the IC chip resulting in higher risks of extremely low K materials (ELK) cracking and/or peeling. If copper pillar bumps are not properly developed, then there is a risk of marginal reliability in terms of chip package interaction (CPI). The situation becomes even more dire in large die sizes, where coefficient of thermal expansion mismatch between silicon and laminate substrate magnifies the stress. While existing copper pillar bumps are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor structure, according to various aspects of the present disclosure.

FIGS. 2, 3, 4, 5, 6, 7, 8, 9, 10, 11, 12, 13, 14, 15, 16, 17, and 18 illustrate fragmentary cross-sectional views of a workpiece during various fabrication stages in the method of FIG. 1, according to various aspects of the present disclosure.

FIG. 19 depicts an exemplary top view of the workpiece shown in FIG. 18, according to various aspects of the present disclosure.

FIG. 20 depicts a fragmentary cross-sectional view of a first alternative semiconductor structure, according to various aspects of the present disclosure.

FIG. 21 is a flow chart of a method for fabricating a second alternative semiconductor structure, according to various aspects of the present disclosure.

FIGS. 22, 23, 24, 25, 26, and 27 illustrate fragmentary cross-sectional views of a workpiece during various fabrication stages in the method of FIG. 21, according to various aspects of the present disclosure.

FIG. 28 depicts an exemplary top view of a third alternative semiconductor structure, according to various aspects of the present disclosure.

FIG. 29 depicts a fragmentary cross-sectional view of the third alternative semiconductor structure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In some packaging technologies, a semiconductor chip (or IC chip) is bonded to a package substrate to form a semiconductor device package and the semiconductor device package is then bonded to a printed circuit board (PCB). The semiconductor chip and the package substrate have different material properties. On the one hand, the semiconductor chip is formed primarily of semiconductor materials (such as silicon, germanium, silicon germanium, or III-V semiconductors), semiconductor oxide (such as silicon oxide), and semiconductor nitride (such as silicon nitride). The package substrate, on the other hand, may be a laminated substrate that includes polymeric materials and metals. For example, the package substrate may be fabricated from, for example, polyimide, a polymer composite laminate, an organic (laminate) material such as bismaleimide-triazine (BT), a polymer-based material such as liquid-crystal polymer (LCP), or the like. The package substrate may also include traces/lines that are formed from suitable conductive materials, such as copper, aluminum, silver, gold, other metals, alloys, combination thereof. As a result, coefficient of thermal expansion (CTE) of the package substrate may be about greater than that of the IC chip. The semiconductor device package may be subject to elevated temperature, for example, during solder reflow process. When the semiconductor device package is cooled down to room temperature, the package substrate may contract more than the IC chip. The deformation may exert stress on the IC chip, and the stress may cause cracks in the passivation structure and cracks and/or peelings of ELK and leading to device failure.

The present disclosure provides a semiconductor structure having metal bump structures and methods of making the same to address these issues. In some embodiments, the metal bump structure includes a textured copper pillar. A percentage of (111) crystal orientation of the textured copper pillar may be equal to or greater than 90%. By providing this textured copper pillar having a lower value of Young's modulus, the risk of this textured copper pillar being deformed due to the stress associated with CPI may be lowered, and the reliability of the IC chip may be advantageously improved. In some embodiments, the copper pillar is fabricated to have a footing profile to increase the contact area between the metal bump structure and the passivation structure thereunder to further reduce stress buildup in certain areas.

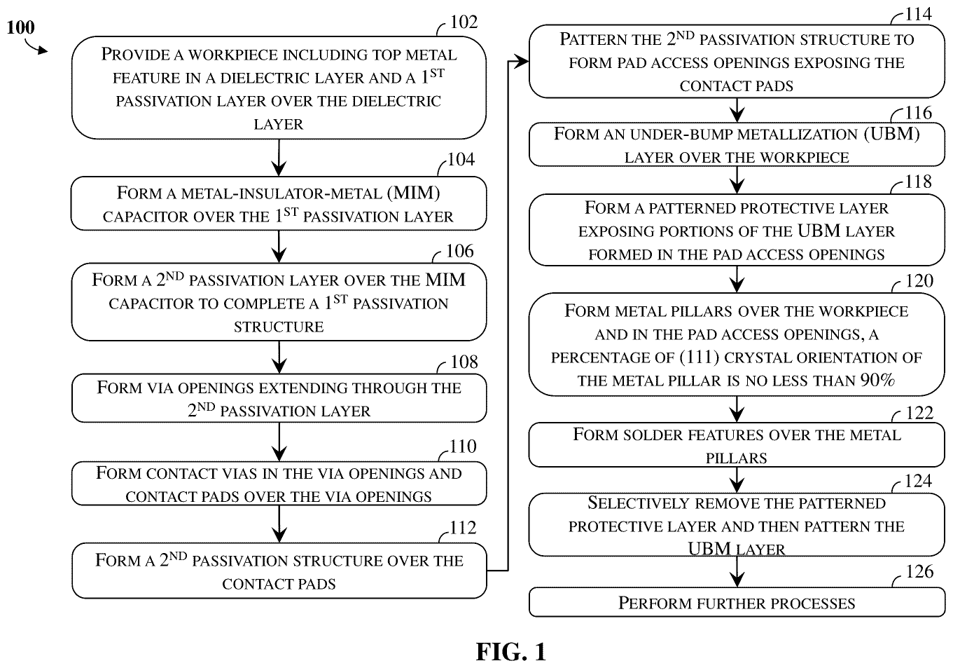

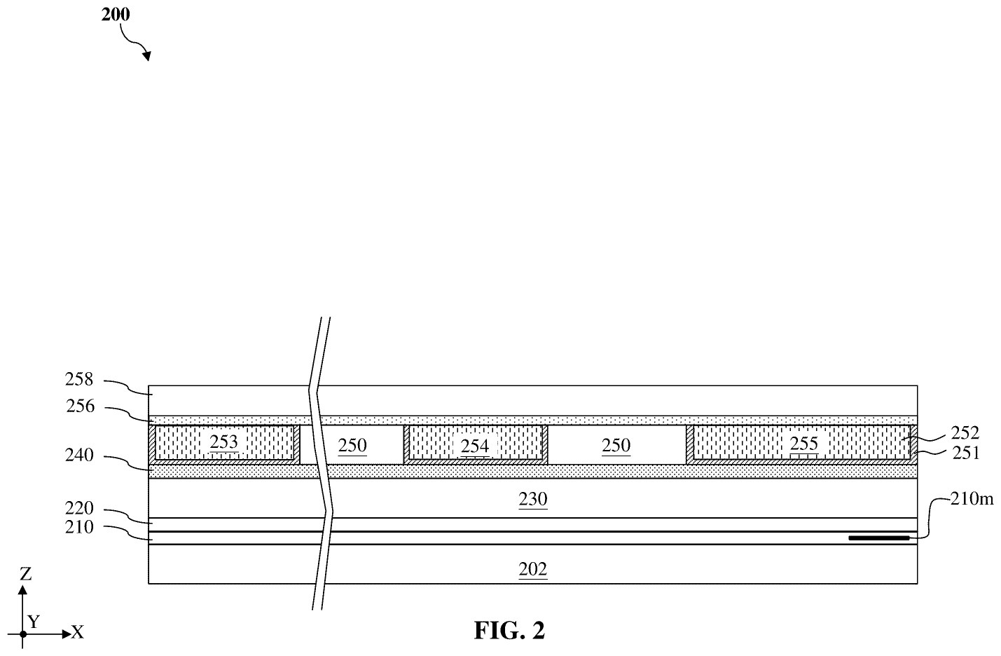

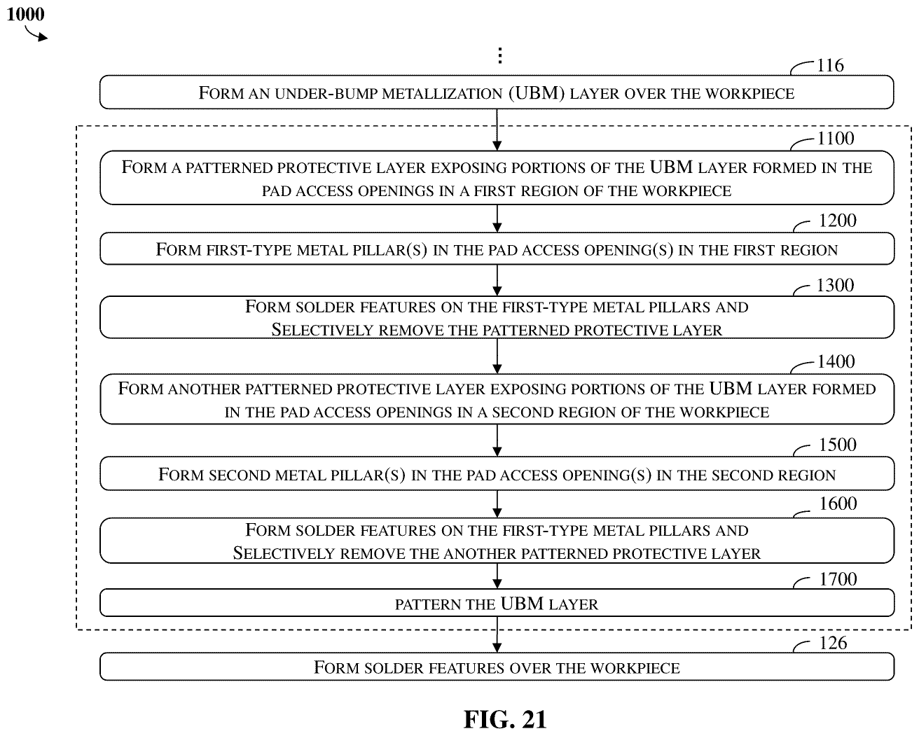

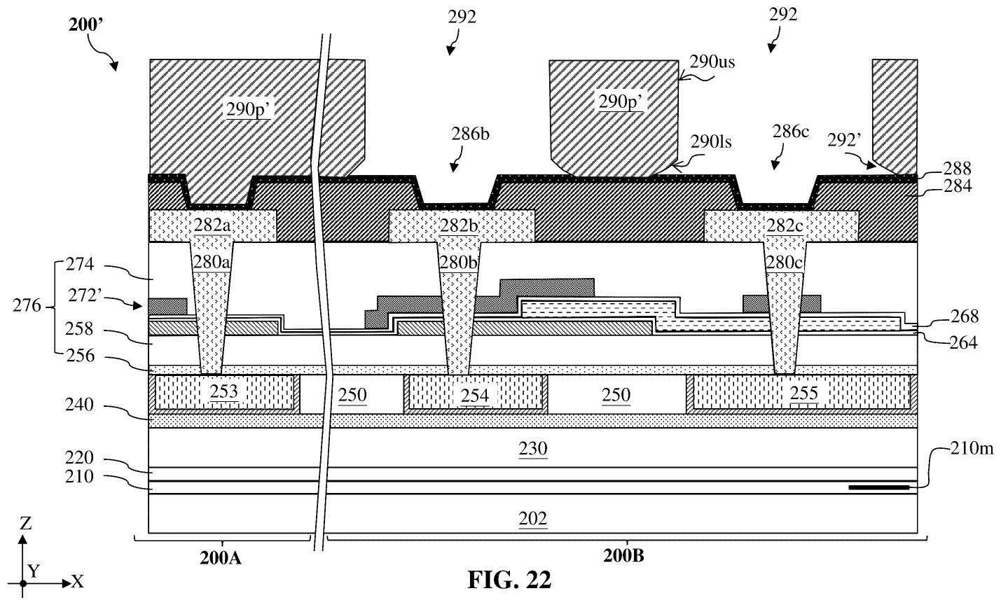

The various aspects of the present disclosure will now be described in more detail with reference to the figures. In that regard, FIG. 1 is a flowchart illustrating a method 100 for fabricating a semiconductor structure, according to embodiments of the present disclosure. Method 100 is described below in conjunction with FIGS. 2-20, which are fragmentary cross-sectional views and/or top views of a workpiece 200 at different stages of fabrication according to embodiments of method 100. FIG. 21 is a flowchart illustrating a method 1000 for fabricating an alternative semiconductor structure, according to embodiments of the present disclosure. Method 1000 is described below in conjunction with FIGS. 22-29, which are fragmentary cross-sectional views and/or top views of a workpiece 200′/200″ at different stages of fabrication according to embodiments of method 1000. Because the workpiece 200/200′/200″ will be fabricated into a semiconductor structure at the conclusion of the fabrication processes, the workpiece may also be referred to as a semiconductor structure 200/200′/200″, as the context requires. Method 100 and method 1000 are merely examples and are not intended to limit the present disclosure to what is explicitly illustrated therein. Additional steps can be provided before, during, and after method 100/1000, and some steps described can be replaced, eliminated, or moved around for additional embodiments of the method. Not all steps are described herein in detail for reasons of simplicity. Additionally, throughout the present application, like reference numerals denote like features, unless otherwise excepted.

Referring to FIGS. 1 and 2, method 100 includes a block 102 where a workpiece 200 is provided. The workpiece 200 includes a substrate 202, which may be made of silicon or other semiconductor materials such as germanium. The substrate 202 may also include a compound semiconductor such as silicon carbide, gallium arsenic, indium arsenide, or indium phosphide. In some embodiments, the substrate 202 may include alloy semiconductor such as silicon germanium, silicon germanium carbide, gallium arsenic phosphide, or gallium indium phosphide. In some embodiments, the substrate 202 may include an epitaxial layer, such as an epitaxial layer overlying a bulk semiconductor. Various microelectronic components may be formed in or on the substrate 202, such as transistor components including source/drain features, gate structures, gate spacers, source/drain contacts, gate contacts, isolation structures including shallow trench isolation (STI), or any other suitable components. Source/drain feature(s) may refer to a source or a drain, individually or collectively dependent upon the context. Transistors formed on the substrate 202 may be planar devices or multi-gate devices. Multi-gate devices include, for example, fin-like field effect transistors (FinFETs) or multi-bridge-channel (MBC) transistors. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

The workpiece 200 also includes a multi-layer interconnect (MLI) structure 210, which provides interconnections (e.g., wiring) between the various microelectronic components of the workpiece 200. The MLI structure 210 may also be referred to as an interconnect structure 210. The MLI structure 210 may include multiple metal layers or metallization layers. In some instances, the MLI structure 210 may include eight (8) to fourteen (14) metal layers. Each of the metal layers includes multiple conductive components embedded in an intermetal dielectric (IMD) layer. The conductive components may include contacts, vias, or metal lines (such as metal line 210m). The IMD layer may be a silicon oxide or silicon-oxide-containing material where silicon exists in various suitable forms. As an example, the IMD layer includes silicon oxide or a low-k dielectric material having k-value (dielectric constant) smaller than that of silicon oxide, which is about 3.9. In some embodiments, the low-k dielectric material includes tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, combinations thereof, or other suitable materials. The conductive components may be formed of any suitable conductive materials. In an embodiment, the metal line 210m is formed of copper. In an embodiment, a percentage of (111) crystal orientation of the copper of the metal line 210m is less than about 30%. That is, when measuring crystal orientations on a cross-section of the copper in any direction, a ratio of (111) crystal orientation to all crystal orientations (e.g., (001) crystal orientation, (111) crystal orientation, (110) crystal orientation) in that cross-section is less than about 30%. In the present disclosure, copper having less than 30% (111) crystal orientation may be referred to as regular copper.

In an embodiment, the workpiece 200 also includes a carbide layer 220 deposited on the MLI structure 210. The deposition process includes chemical vapor deposition (CVD), physical vapor deposition (PVD), atomic layer deposition (ALD), or combinations thereof. Any suitable type of carbide material such as silicon carbide (SiC) can be used in the carbide layer 220. In an embodiment, an oxide layer 230 is deposited on the carbide layer 220. Any suitable deposition process for the oxide layer 230 may be used, including CVD, flowable CVD (FCVD), spin-on coating, PVD, ALD, or combinations thereof. In an embodiment, the oxide layer 230 includes undoped silicon oxide.

The workpiece 200 also includes an etch stop layer (ESL) 240 deposited on the oxide layer 230. The ESL 240 may include silicon carbonitride (SiCN), silicon oxycarbide (SiOC), silicon carbide (SiC), silicon oxycarbonitride (SiOCN), or silicon nitride (SiN), or combinations thereof and may be formed by chemical vapor deposition (CVD), physical vapor deposition (PVD), atomic layer deposition (ALD), or combinations thereof.

The workpiece 200 also includes a dielectric layer 250 deposited on the ESL 240. A composition of the dielectric layer 250 may be similar to that of the oxide layer 230. In some embodiments, the dielectric layer 250 includes undoped silica glass (USG) or silicon oxide. The dielectric layer 250 may be deposited using CVD, flowable CVD (FCVD), spin-on coating, PVD, ALD, or combinations thereof.

The workpiece 200 also includes a number of lower contact features (e.g., a lower contact feature 253, a lower contact feature 254, and a lower contact feature 255) formed in the dielectric layer 250. The formation of the lower contact features may include patterning of the dielectric layer 250 to form trenches and deposition of a barrier layer 251 and a metal fill layer 252 in the trenches. In some embodiments, the barrier layer 251 may include titanium nitride or tantalum nitride and may be conformally deposited using PVD, CVD, metalorganic CVD (MOCVD), or a suitable method. In one embodiment, the barrier layer 251 may include tantalum nitride. The metal fill layer includes a metal or metal alloy such as copper (Cu), cobalt (Co), nickel (Ni), aluminum (Al), tungsten (W), ruthenium (Ru), titanium (Ti), or combinations thereof. In the depicted example, the metal fill layer 252 includes regular copper (Cu) and may be deposited using electroplating or electroless plating. It is noted that, for embodiments in which the metal fill layer 252 includes regular copper, the electroplating or electroless plating process may form the metal fill layer 252 with a convex top surface. After the barrier layer 251 and the metal fill layer 252 are deposited, a planarization process, such as a chemical mechanical planarization (CMP) process, may be performed to remove excess portions of barrier layer 251 and metal fill layer 252 to form the lower contact features 253, 254 and 255. After the performing of the planarization process, the metal fill layer 252 has a substantially planar top surface. Although the lower contact features 253, 254, and 255 are disposed below upper contact features (such as contact pads 282a, 282b, and 282c), the lower contact features 253, 254, and 255 are sometimes referred to as top metal (TM) contacts 253, 254, and 255, respectively.

The workpiece 200 also includes an etch stop layer 256 formed directly on the dielectric layer 250. In an embodiment, the etch stop layer 256 is deposited on the dielectric layer 250 by chemical vapor deposition (CVD), physical vapor deposition (PVD), atomic layer deposition (ALD), or combinations thereof. The etch stop layer 256 may include silicon carbonitride (SiCN), silicon nitride (SiN), other suitable materials, or combinations thereof. In the present embodiments, the etch stop layer 256 is in direct contact with top surfaces of the lower contact features 253, 254, and 255.

The workpiece 200 also includes a first passivation layer 258 deposited over the etch stop layer 256. The first passivation layer 258 may include any suitable material (e.g., silicon nitride) and may be deposited using plasma-enhanced CVD (PECVD). Gaseous precursors used to form the first passivation layer 258 may include ammonia (NH₃), silane (SiH₄), and nitrogen (N₂).

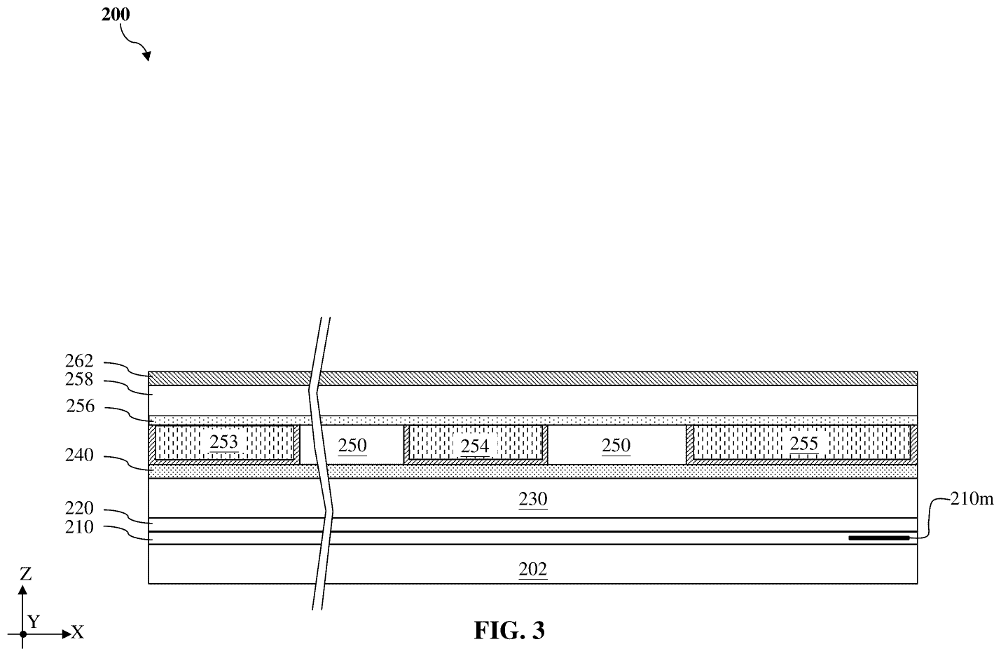

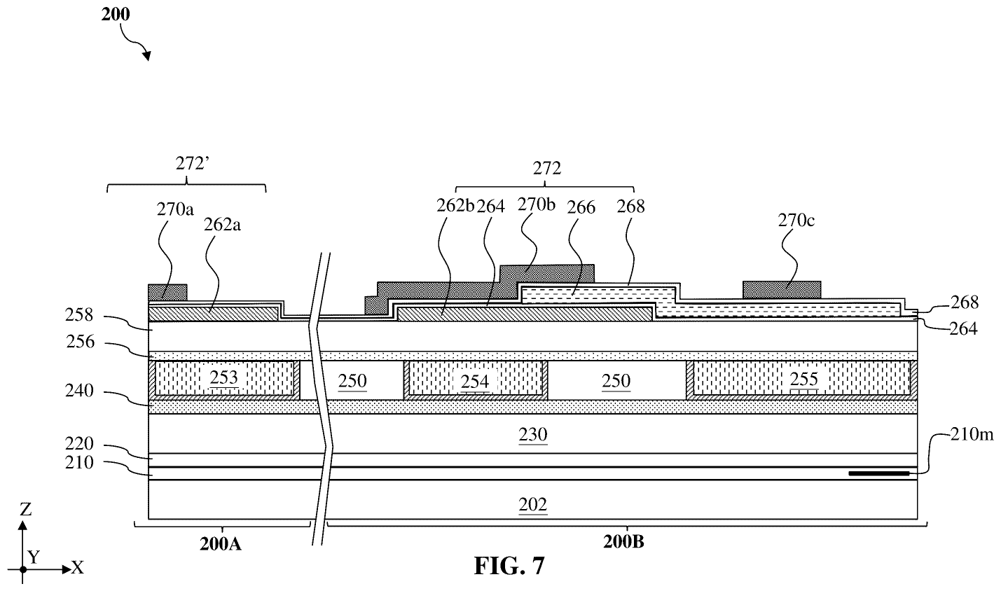

Referring to FIGS. 1 and 3-7, method 100 includes a block 104 where a metal-insulator-metal (MIM) capacitor 272 is formed over the first passivation layer 258 and in a region 200B of the workpiece 200. As shown in FIGS. 3-7, forming the MIM capacitor 272 involves multiple processes, including those for formation and patterning of a bottom conductor plate 262b, a middle conductor plate 266, and a top conductor plate 270b in the region 200B of the workpiece 200. In the present embodiments, a MIM capacitor 272′ is also formed in a region 200A of the workpiece 200 along with the formation of the MIM capacitor 272. It is understood that, in some embodiments, only a fragmentary portion of the MIM capacitor 272′ is shown in FIG. 7. Referring first to FIG. 3, a first conductive layer 262 is formed directly on the first passivation layer 258. The first conductive layer 262 may be deposited on the first passivation layer 258 using PVD, CVD, or MOCVD. In some embodiments, the first conductive layer 262 may include titanium (Ti), tantalum (Ta), titanium nitride (TiN), tantalum nitride (TaN), copper (Cu), cobalt (Co), nickel (Ni), tungsten (W), aluminum (Al), or other suitable materials. The first conductive layer 262 may cover an entire top surface of the workpiece 200.

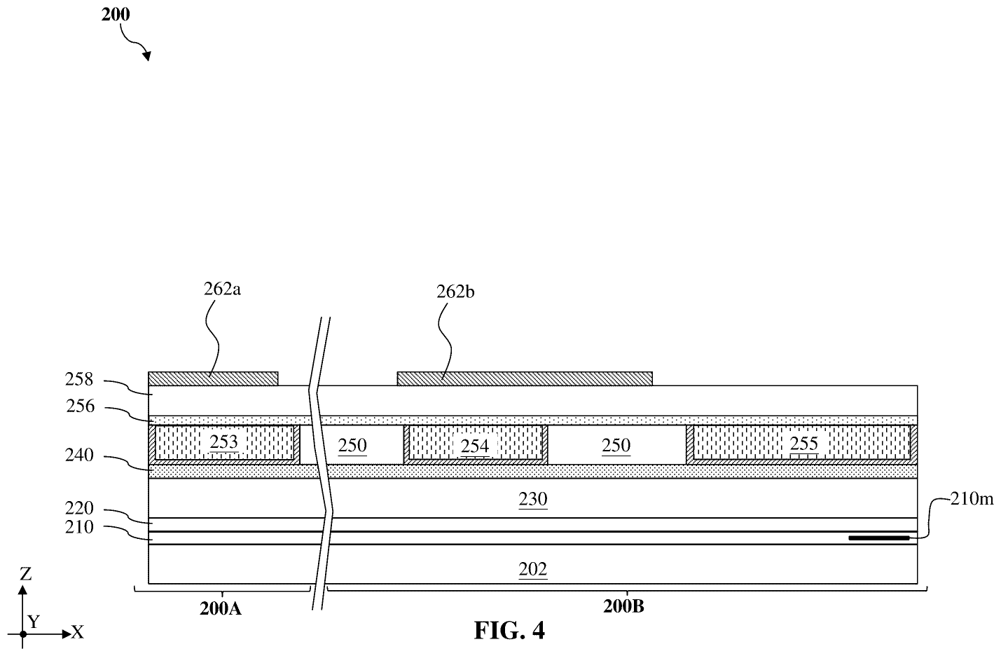

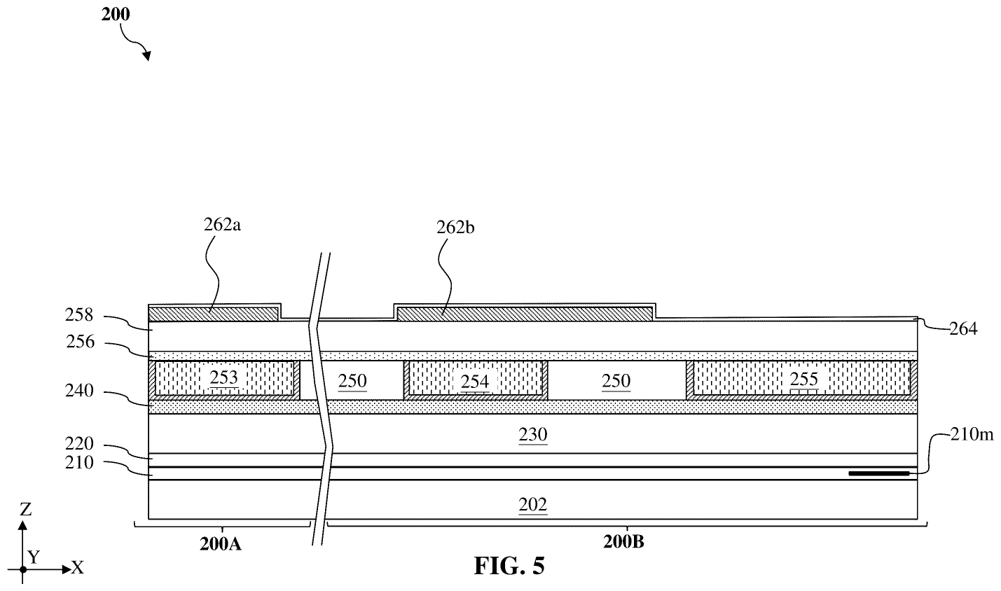

Referring to FIG. 4, the first conductive layer 262 is patterned to form a bottom conductor plate 262a directly over the lower contact feature 253 and in the region 200A and a bottom conductor plate 262b directly over the lower contact feature 254 and in the region 200B. The patterning may include deposition of a hard mask layer over the first conductive layer 262, formation of a photoresist layer over the hard mask layer, patterning of the photoresist layer using photolithography, etching of the hard mask layer using the patterned photoresist layer as an etch mask, and then etching of the first conductive layer 262 using the patterned hard mask as an etch mask. The hard mask layer may be selectively removed after forming the bottom conductor plates 262a and 262b. Referring to FIG. 5, a first insulator layer 264 is deposited over the workpiece 200. As shown in FIG. 5, after the first conductive layer 262 is patterned to form the bottom conductor plates 262a and 262b, the first insulator layer 264 is deposited. In an embodiment, the first insulator layer 264 is conformally deposited to have a generally uniform thickness over the top surface of the workpiece 200 (e.g., having about the same thickness on top and sidewall surfaces of the first conductor plate 262′). The first insulator layer 264 may be deposited using CVD, ALD, or a suitable deposition method and may be a high-k dielectric layer that includes hafnium oxide, aluminum oxide, zirconium oxide, titanium oxide, tantalum oxide, or a combination thereof.

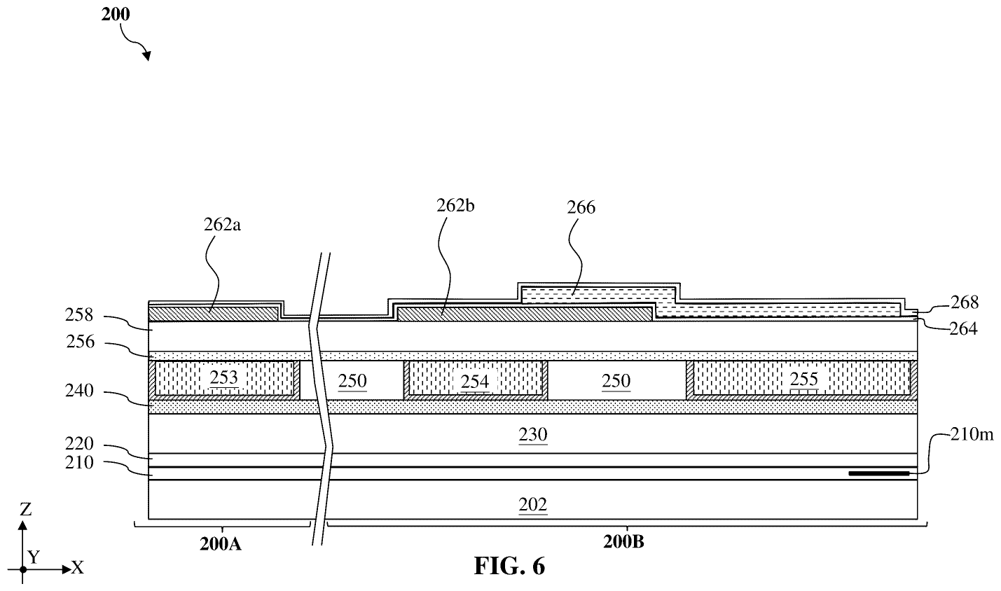

Referring to FIG. 6, a middle conductor plate 266 is formed on the first insulator layer 264, over the lower contact feature 255, and in the region 200B. The middle conductor plate 266 is vertically overlapped with the bottom conductor plate 262b. A composition and formation of the middle conductor plate 266 may be similar to those of the bottom conductor plate 262a/262b. A second insulator layer 268 is then formed over the workpiece 200, including over the middle conductor plate 266. A composition and formation of the second insulator layer 268 may be similar to those of the first insulator layer 264. Referring to FIG. 7, a top conductor plate 270a is formed over the second insulator layer 268 and in the region 200A, a top conductor plate 270b and a dummy conductor plate 270c are formed over the second insulator layer 268 and in the region 200B. The top conductor plate 270a is vertically overlapped with the bottom conductor plate 262a, the top conductor plate 270b and the dummy conductor plate 270c are vertically overlapped with the middle conductor plate 266. The formation and composition of the conductor plate 270a/270b/270c may be similar to that of the bottom conductor plate 262a/262b, and repeated description is omitted for reason of simplicity. After the formation of the top conductor plate 270a and the top conductor plate 270b, the structure of a MIM capacitor 272 formed in the region 200B is finalized, and the structure of a MIM capacitor 272′ formed in the region 200A is finalized. It is understood that the MIM capacitor 272 and the MIM capacitor 272′ may have different configurations. For example, the MIM capacitor 272/272′ may include other suitable number of conductor plates (e.g., four or more), and each two adjacent conductor plates are isolated by a corresponding insulator layer. It should be noted that methods and structures of the present disclosure also apply to structures that do not include the MIM capacitor 272/272′.

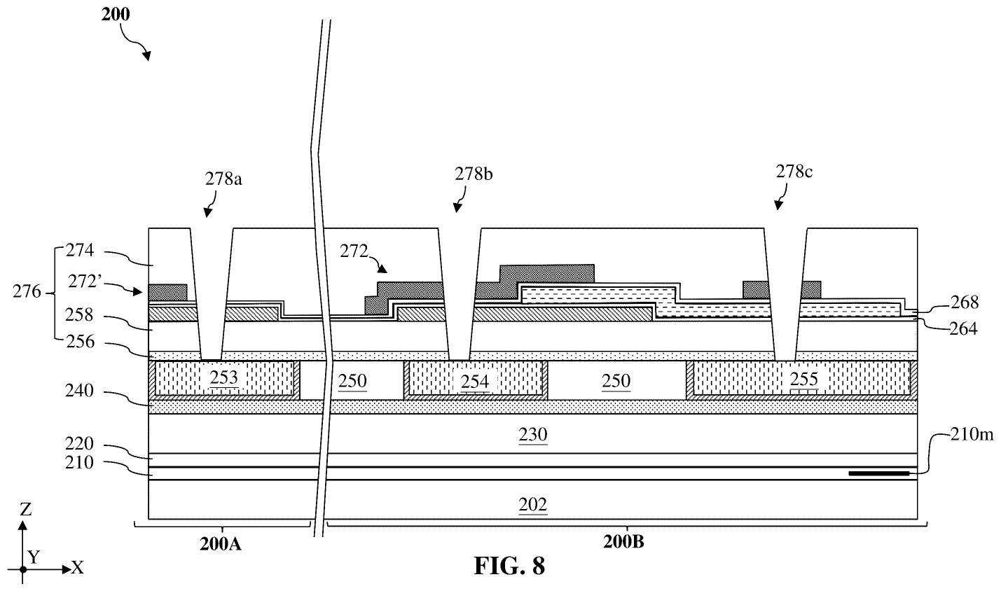

Referring to FIGS. 1 and 8, method 100 includes a block 106 where a second passivation layer 274 is formed over the MIM capacitors 272 and 272′. In some embodiments, the second passivation layer 274 may include a dielectric layer or two or more dielectric layers formed by any suitable materials such as silicon oxide or silicon nitride and may be formed by any suitable deposition processes (e.g., plasma-enhanced chemical vapor deposition (PECVD)). As shown in FIG. 8, the MIM capacitor 272/272′ is sandwiched between the second passivation layer 274 and first passivation layer 258. In some embodiments, the etch stop layer 256, the first passivation layer 258, the MIM capacitor 272/272′, and the second passivation layer 274 may be collectively referred to as a first passivation structure 276. The first passivation layer 258 and the second passivation layer 267 protect the MIM capacitor 272/272′ from damages due to stress or crack propagation.

Still referring to FIGS. 1 and 8, method 100 includes a block 108 where a number of via openings (such as via openings 278a, 278b, and 278c) are formed to penetrate through the first passivation structure 276. In the depicted embodiment, the via opening 278a is formed in the region 200A, extends through the bottom conductor plate 262a of the MIM capacitor 272′ and exposes the lower contact feature 253. The via opening 278b is formed in the region 200B, extends through the top and bottom conductor plates 262b and 270b of the MIM capacitor 272, and exposes the lower contact feature 254. The via opening 278c is formed in the region 200B, extends through the middle conductor plate 266 of the MIM capacitor 272, and exposes the lower contact feature 255. The formation of the via openings (such as via openings 278a, 278b, and 278c) involves performing a combination of lithography and etching processes. In an embodiment, the via openings 278a, 278b, and 278c may be formed using dry etching, such as reactive ion etching (RIE). In some embodiments, the formation of the via openings 278a, 278b, and 278c may include use of oxygen, an oxygen-containing gas, hydrogen, a fluorine-containing gas (e.g., CF₄, SF₆, NF₃, BF₃, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

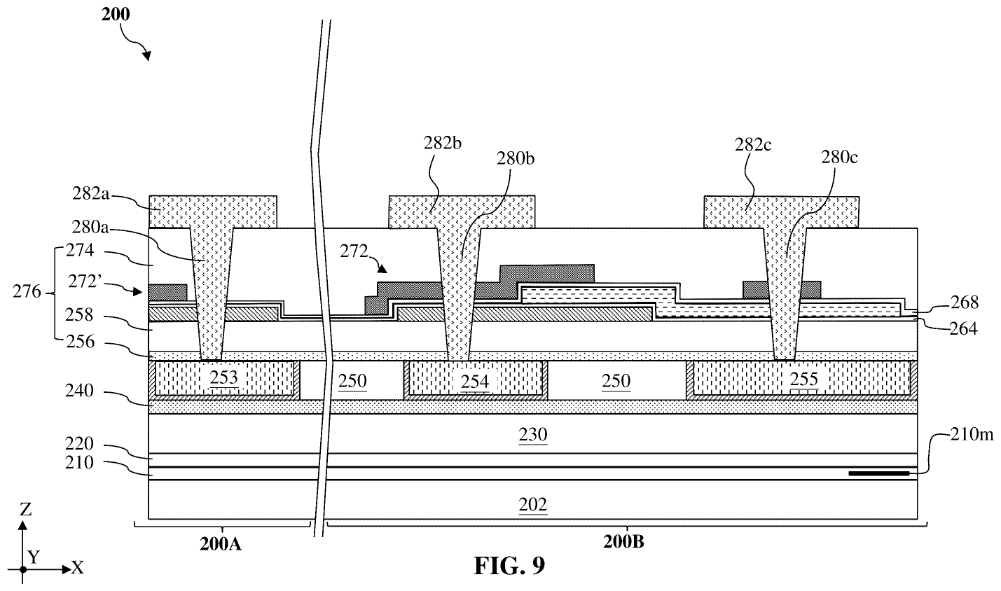

Referring to FIGS. 1 and 9, method 100 includes a block 110 where contact vias (such as contact vias 280a, 280b, and 280c) are formed in the via openings (such as the via openings 278a, 278b, and 278c) and contact pads (such as contact pads 282a, 282b, and 282c) are formed over the via openings. In an embodiment, a conductive material is deposited over the workpiece 200 and into the via openings 278a, 278b, and 278c. In some embodiments, the conductive material includes a bi-layer structure. More specifically, to deposit the conductive material, a barrier layer (not separately labeled) is first conformally deposited over the second passivation layer 274 and into the via openings 278a, 278b, and 278c using a suitable deposition technique, such as ALD, PVD or CVD and then a metal fill layer (not separately labeled) is deposited over the barrier layer using ALD, PVD, CVD, electroless plating, or electroplating. The barrier layer may include titanium nitride (TiN), tantalum nitride (TaN), or another metal nitride. The metal fill layer may be formed of copper (Cu), aluminum (Al), aluminum copper (Al—Cu), or other suitable materials. In an embodiment, the metal fill layer includes aluminum (Al), the barrier layer 288a includes tantalum nitride (TaN). A planarization process (e.g., CMP) may be then performed after forming the metal fill layer. Portions of the conductive material formed in the via openings 278a, 278b, and 278c may be referred to as contact vias 280a, 280b, and 280c, respectively.

The conductive material may be then etched to form a number of contact pads (such as contact pads 282a, 282b, and 282c) over the second passivation layer 274. In some embodiments, a photoresist layer may be formed over the conductive material and then patterned. While using the patterned photoresist layer as an etch mask, an etching process may be performed to form the contact pads 282a, 282b, and 282c. It is noted that, the contact pads 282a, 282b, and 282c and the contact vias 280a, 280b, and 280c are formed from the same conductive material during a common deposition process and thus have same composition. That is, the contact via 280a/280b/280c and the contact pad 282a/282b/282c thereon are portions of an integral conductive feature and there is no physical interface therebetween. In some embodiments, the contact pads (such as contact pads 282a, 282b, and 282c) may be referred to as upper contact features and may be part of a redistribution layer (RDL) to reroute bond connections between upper and lower layers.

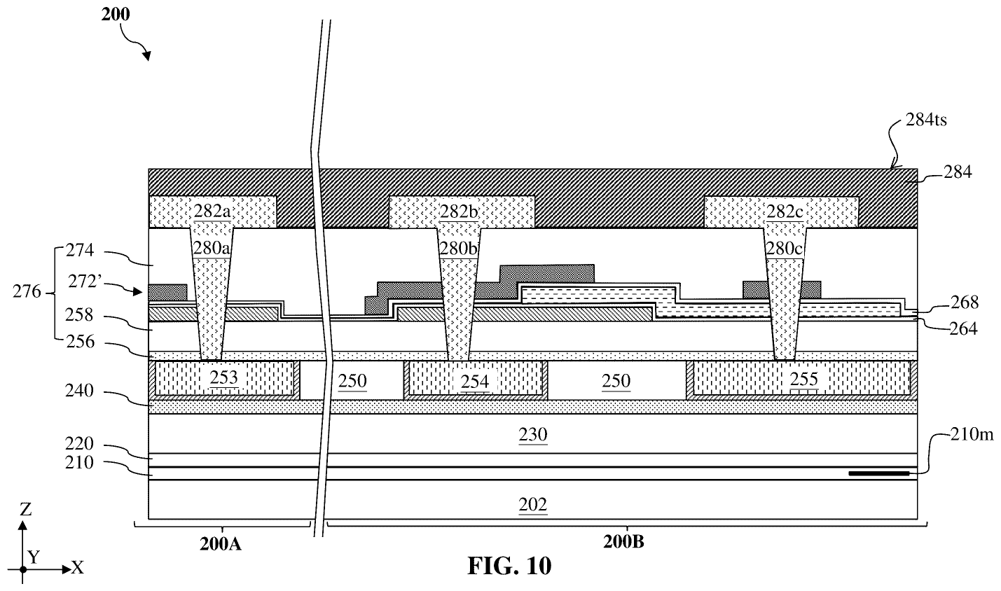

Referring to FIGS. 1 and 10, method 100 includes a block 112 where a second passivation structure 284 is formed over the contact pads 282a, 282b, and 282c. In some embodiments, the second passivation structure 284 may be a multi-layer structure. For example, the second passivation structure 284 may include a passivation layer (e.g., silicon nitride formed by CVD, PECVD, or a suitable method) and a polymer layer formed on the passivation layer. In some embodiments, the polymer layer may include polyimide and may be deposited using spin-on coating. In some other embodiments, the second passivation structure 284 may be a single layer structure. As shown in FIG. 10, the second passivation structure 284 is formed over the workpiece 200, including on top surfaces and along sidewall surfaces of the contact pads 282a, 282b, and 282c and on the second passivation layer 274. After forming the second passivation structure, a planarization process (e.g., CMP) may be performed to the workpiece 200 to provide a planar top surface 284ts.

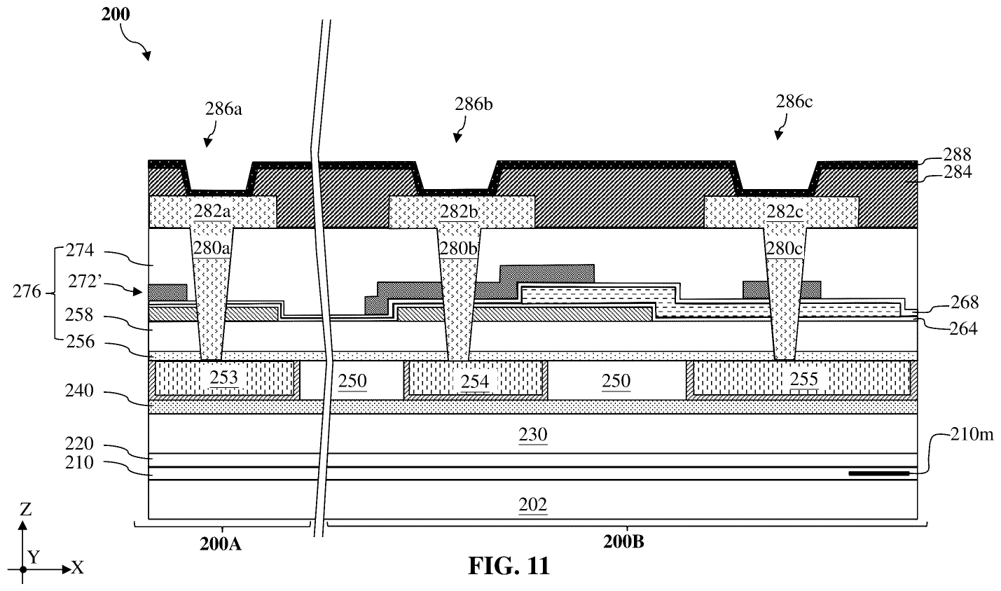

Referring to FIGS. 1 and 11, method 100 includes a block 114 where the second passivation structure 284 is patterned to form pad access openings to expose the contact pads. In embodiments depicted in FIG. 11, pad access openings 286a, 286b, and 286c are formed to extend through the second passivation structure 284 to expose the contact pad 282a, the contact pad 282b, and the contact pad 282c, respectively. In some embodiments, a dry etch process may be performed to etch through the second passivation structure 284. An example dry etch process may include use of hydrogen (H₂), a fluorine-containing gas (e.g., CF₄, SF₆, NF₃, BF₃, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBr₃), an iodine-containing gas.

Still referring to FIGS. 1 and 11, method 100 includes a block 116 where an under-bump metallization (UBM) layer 288 is formed over the workpiece 200. After forming the pad access openings (such as the pad access openings 286a, 286b, and 286c), the UBM layer 288 is deposited on the workpiece 200, including in the pad access openings 286a, 286b, and 286c. In an embodiment, the UBM layer 288 includes a diffusion barrier layer (not separately labeled), which may be formed of titanium, tantalum, titanium nitride, tantalum nitride, or the like. The diffusion barrier layer prevents or reduces electromigration of copper or oxygen diffusion into copper. The UBM layer 288 may also include a seed layer (not separately labeled) formed on the diffusion barrier layer. The seed layer may be formed of copper alloys that include silver, chromium, nickel, tin, gold, and combinations thereof.

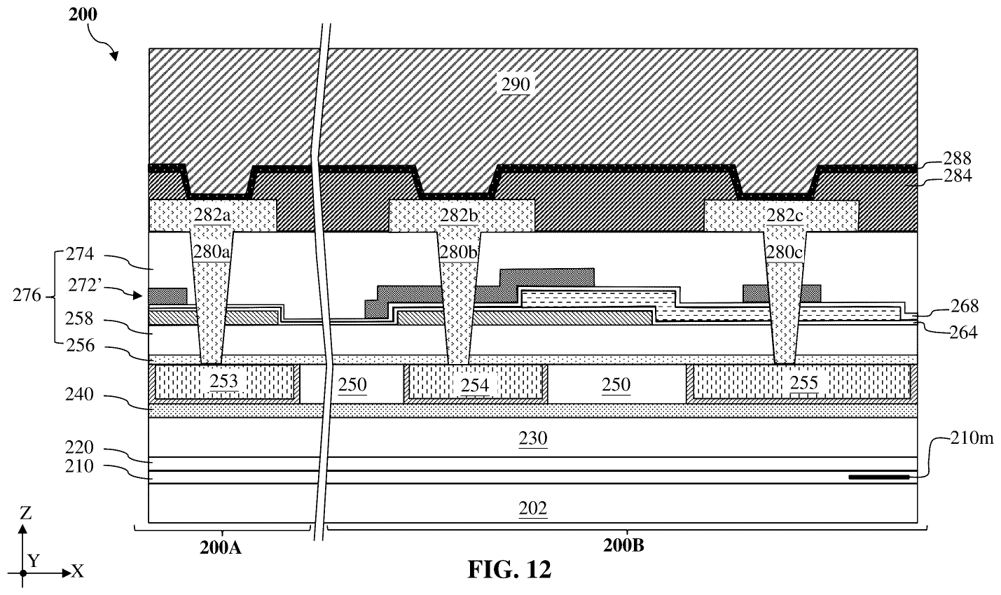

Referring to FIGS. 1 and 12-13, method 100 includes a block 118 where a protective layer 290 is formed over the workpiece 200 and patterned to form openings 292 exposing portions of the UBM layer 288 formed in the pad access openings (such as the pad access openings 286a, 286b, and 286c). Referring first to FIG. 12, the protective layer 290 is formed over the workpiece 200. In an embodiment, the protective layer 290 includes a photoresist layer. The photoresist layer may be blanketly deposited over the workpiece 200 using spin-on coating. That is, the photoresist layer is formed in and over the pad access openings (such as the pad access opening 286a) in the region 200A and pad access openings (such as the pad access openings 286b, and 286c) in the region 200B.

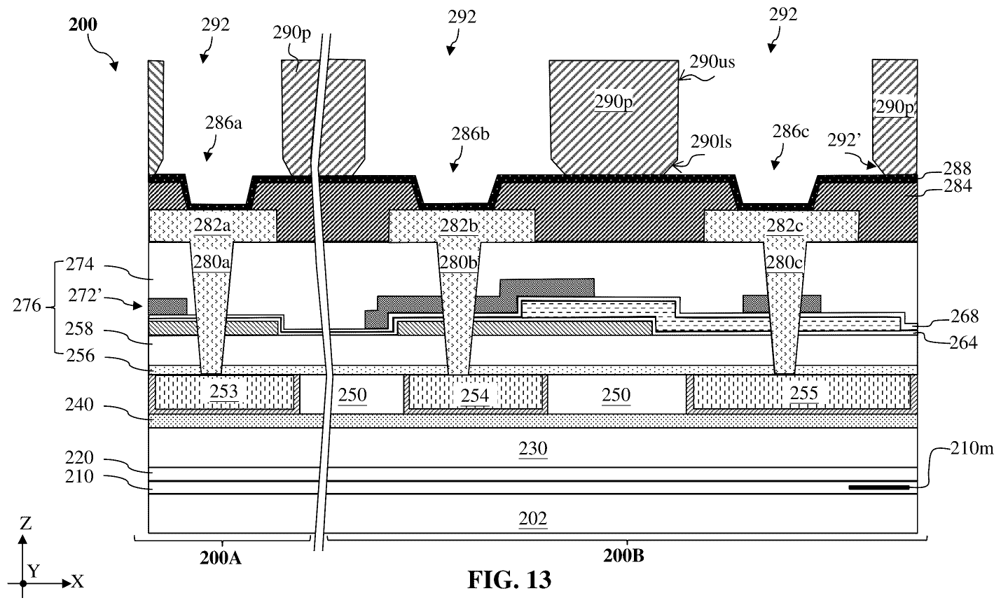

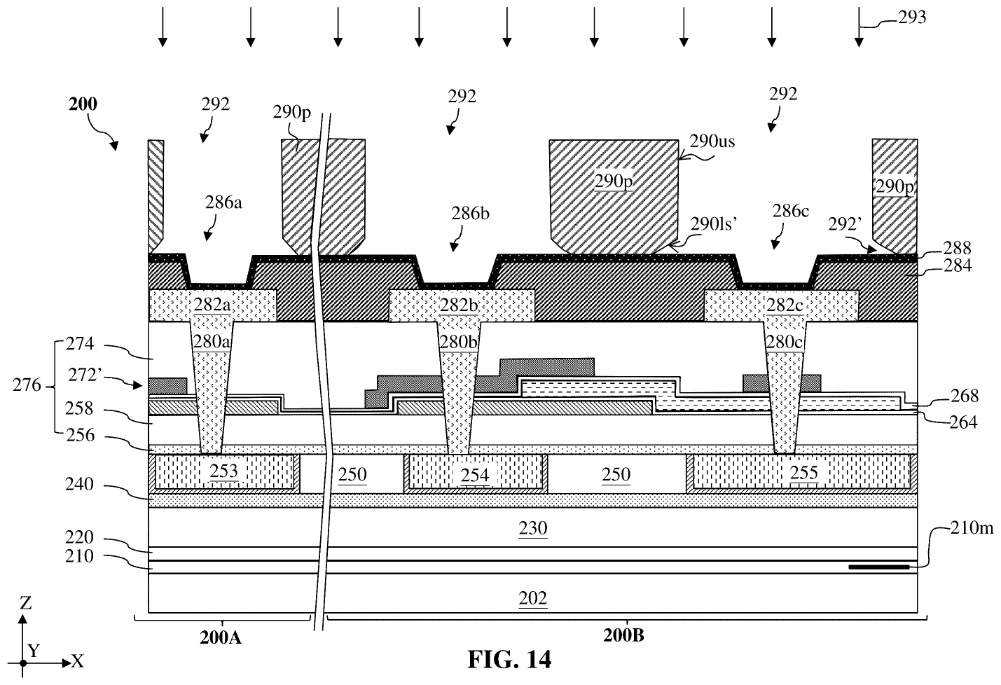

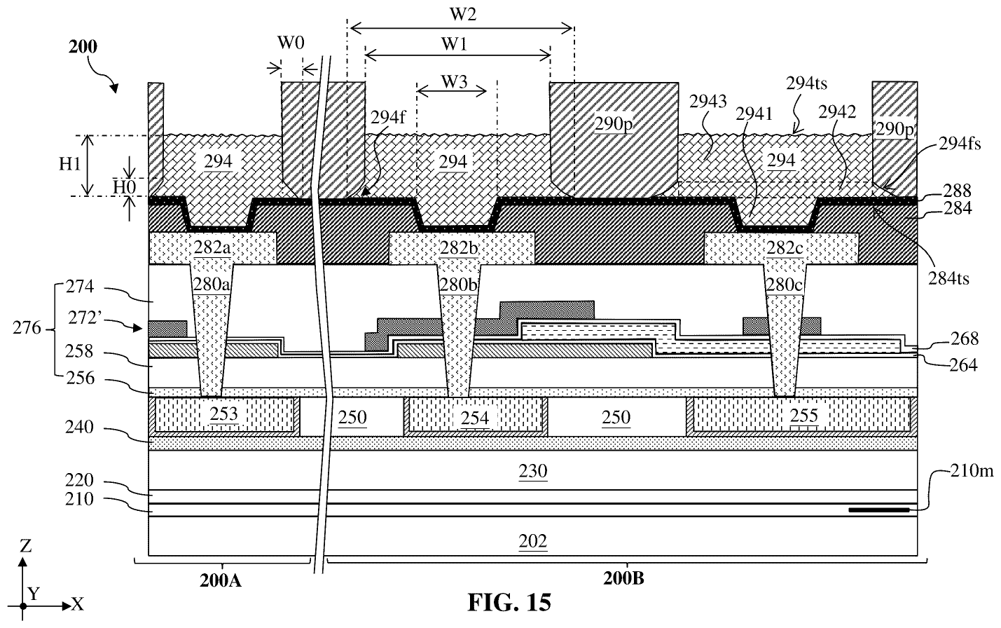

Referring then to FIG. 13, photolithography techniques (e.g., exposure, developing) are used to pattern the protective layer 290. The patterned protective layer 290 may be referred to as the protective layer 290p. As depicted in FIG. 13, in the present embodiments, the protective layer 290p defines openings 292 exposing portions of the UBM layer 288 formed in the pad access openings (such as the pad access openings 286a, 286b, and 286c). In order to increase a contact area between the to-be-formed bump structure 298 (e.g., copper pillar bumps) and the second passivation structure 284 to help spread stress across the bump area and thus reduce or even prevent stress-induced damages, the to-be-formed metal pillar (e.g., metal pillar 294) of the bump structure 298 may be formed to have a wider middle portion 2942 (shown in FIG. 15) and a narrower top portion 2943 (shown in FIG. 15). To achieve this, parameters associated with the patterning of the protective layer 290 may be adjusted such that each of the openings 292 undercuts the protective layer 290p. In one example process, the protective layer 290 shown in FIG. 12 is a negative photoresist. During exposure, the upper portion of the protective layer 290 receives more intense irradiation and has a higher extent of crosslinking while the lower portion of the protective layer 290 receives less irradiation and has a lower extent of crosslinking. During the subsequent developing, the developer removes the lower portion faster than it removes the upper portion, thereby forming undercuts 292′ shown in FIG. 13. Other arrangements are possible and the protective layer 290 may be a positive photoresist in other arrangements. In the present embodiments, as exemplary shown in FIG. 13, an upper portion 290us of a sidewall surface of the protective layer 290p is substantially vertical, and due to the formation of the undercuts 292′, a lower portion 2901s of the sidewall surface of the protective layer 290p is a slanted surface that tilts inward. A boundary of the opening 292 is defined by the sidewall surface (such as the upper portion 290us and the lower portion 2901s) of the protective layer 290p. In an embodiment, referring to FIG. 14, after forming the protective layer 290p, a surface treatment process 293 is performed to clean the surface of the UBM layer 288. The surface treatment process 293 may also etch the lower portion of the protective layer 290p, thereby enlarging the undercuts 292′ and thus enlarging the opening 292. In an embodiment, after performing the surface treatment process 293, a slope of the lower portion 2901s of the sidewall surface of the protective layer 290p is decreased. The lower portion 2901s having a decreased slope may be referred to as the lower portion 2901s′.

Referring to FIGS. 1 and 15, method 100 includes a block 120 where a conductive material 294 is formed in the pad access openings and over the workpiece 200. In the present embodiments, while using the patterned protective layer 290p as a mask, the conductive material 294 is formed in the pad access opening 286a/286b/286c and in the opening 292 to contact the UBM layer 288. The conductive material 294 includes substantially a layer including pure elemental copper, copper containing unavoidable impurities, or copper alloys containing minor amounts of elements such as tantalum, indium, tin, zinc, manganese, chromium, titanium, germanium, strontium, platinum, magnesium, aluminum or zirconium. The conductive material 294 may be referred to as a metal pillar 294 or a copper pillar 294.

In the present embodiments, each of the copper pillars 294 tracks the shape of a lower portion of the openings 292 and the shape of the exposed portion of the UBM layer 288. That is, the copper pillar 294 has a bottom portion 2941 in the pad access opening 286a/286b/286c, a middle portion 2942 on the bottom portion 2941 and filling the undercuts 292′, and a top portion 2943 on the middle portion 2942 and confined by the upper portion 290us of the sidewall surface of the protective layer 290p. As depicted in FIG. 15, the bottom portion 2941 is on and in direct contact with the portion of the UBM layer 288 formed in the pad access opening 286a/286b/286c. In the present embodiment, the bottom portion 2941 has a non-uniform width. More specifically, a width of the bottom portion 2941 gradually increases bottom to top. The middle portion 2942 has a part 294f filling the undercuts 292′. The part 294t (and thus the middle portion 2942) has a slanted sidewall surface that tilted outward. Due to the formation of the part 294f, the copper pillar 294 has a footing profile. The part 294f has a width W0 along the X direction and a height H0 along the Z direction. In an embodiment, the width W0 may be in a range between about 0.1 μm and about 5 μm, and the height H0 may be in a range between about 0.2 μm and about 3 μm. In the present embodiments, the middle portion 2942 also has a non-uniform width, and its width gradually decreases bottom to top. The top portion 2943 has a substantially vertical sidewall surface and has a uniform width W1 bottom to top. It is noted that, the middle portion 2942 spans a width W2 along the X direction, the bottom portion 2941 spans a width W3 along the X direction. The width W2 is greater than the width W1, and the width W1 is greater than the width W3. In some embodiments, without reducing the pitch between two adjacent metal bumps, the stress may be advantageously reduced by forming the copper pillar 294 having a footing profile. A ratio of the width W2 to the width W1 is in a range between about 1.15 and 1.5. If the ratio is less than 1.15, the stress may not be spread out efficiently. If the ratio is greater than 1.5, a distance between middle portions of two adjacent copper pillars 294 may be too small, increasing the circuit short risk. In an embodiment, 5 μm ≤W1≤65 μm, and 5 μm<W2≤75 μm. The combination of the middle portion 2942 and the top portion 2943 of copper pillar 294 has a height H1 along the Z direction. In an embodiment, the height H1 is in a range between about 10 μm and about 40 μm.

The copper pillar 294 may be formed by sputtering, printing, electroplating, electroless plating, and/or chemical vapor deposition (CVD) methods. For example, electro-chemical plating (ECP) is carried out to form the copper pillar 294. The plating solution may include, e.g., copper sulfate, and may have additives such as bis(3-sulfopropyl)disulfide, polyethylene glycol, gelatin, sodium dodecyl sulfate, polyacrylic acid, and/or glycerol. In the present embodiments, a percentage of (111) crystal orientation of the copper pillar 294 is greater than that of the regular copper. In an embodiment, a ratio of the percentage of (111) crystal orientation of the copper pillar 294 to the percentage of (111) crystal orientation of the copper pillar 294 is greater than 3. In an embodiment, the copper pillar 294 has more than 90% (111) crystal orientation. That is, when measuring crystal orientations on any cross-section of the copper pillar 294, a (111) crystal orientation has a proportion of 90% or more among all crystal orientations (e.g., (100) crystal orientation, (110) crystal orientation, (111) crystal orientation) on that cross-section of the copper pillar 294. In the present disclosure, this type of copper that has more than 90% (111) crystal orientation may be referred to as textured copper. In some embodiments, the copper pillar 294 has more than 97% (111) crystal orientation. By forming the textured copper pillar 294 having a higher proportion of (111) crystal orientation and a lower Young's modulus than those of the regular copper, the risk of the copper pillar 294 being deformed due to the stress associated with CPI may be lowered.

Since the textured copper pillar 294 having more than 90% (111) crystal orientation, a top surface 294ts of the copper pillar 294 has a relatively rough surface texture made up of a series of peaks and valleys. These peaks and valleys increases the overall contact area between the copper pillar 294 and the solder feature 296 that will be formed on the copper pillar 294. In an embodiment, an average roughness Ra of the top surface 294ts is between about 30 μm and about 130 μm. Although the top surface 294ts is a rough surface, when viewed as a whole, the top surface 294ts is substantially parallel to the top surface 284ts of the planarized second passivation structure 284. That is, the top surface 294ts is a substantially planar top surface.

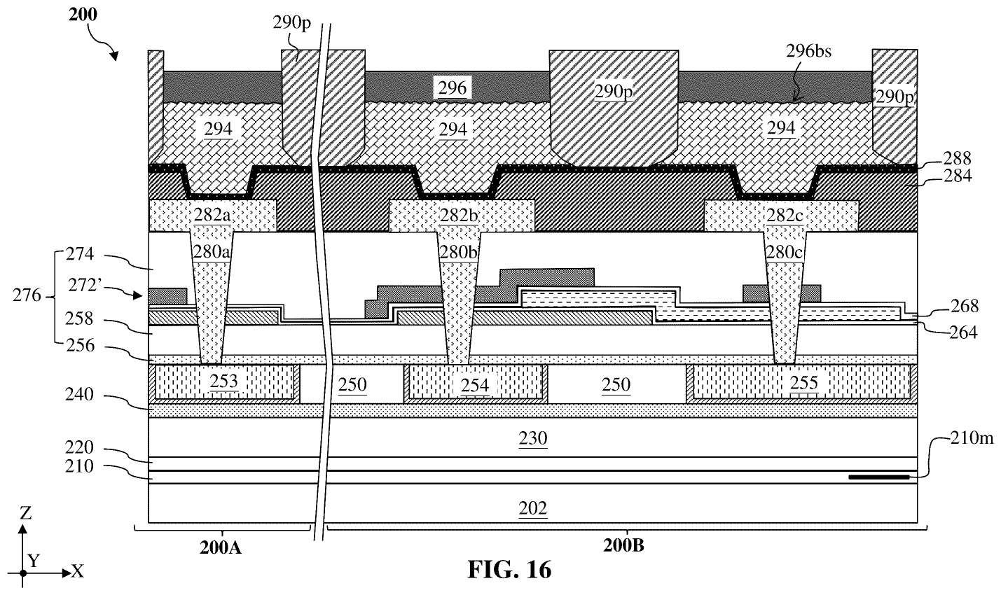

Referring to FIGS. 1 and 16, method 100 includes a block 122 where solder features 296 are formed over the copper pillars 294 and in the openings 292. The solder features 296 may be formed by a plating process. In some implementations, the solder features 296 may include nickel (Ni), tin (Sn), tin-lead (SnPb), gold (Au), silver (Ag), palladium (Pd), indium (In), nickel-palladium-gold (NiPdAu), nickel-gold (NiAu), SnAg, SnPb, SnAgCu, or other suitable metal alloy. A bottom surface of the solder feature 296 in direct contact with the top surface 294ts of the copper pillar 294. In the depicted embodiments, after forming the solder feature 296, the top surface of the protective layer 290p is above the top surface of the solder feature 296. That is, the protective layer 290p still separates two adjacent copper pillars 294 as well as two adjacent solder features 296 deposited thereon.

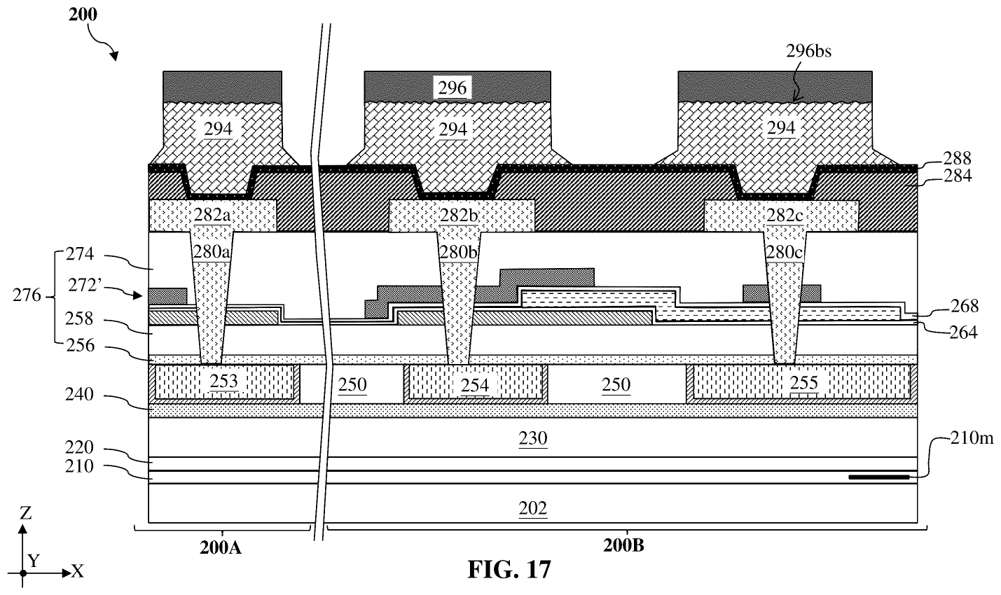

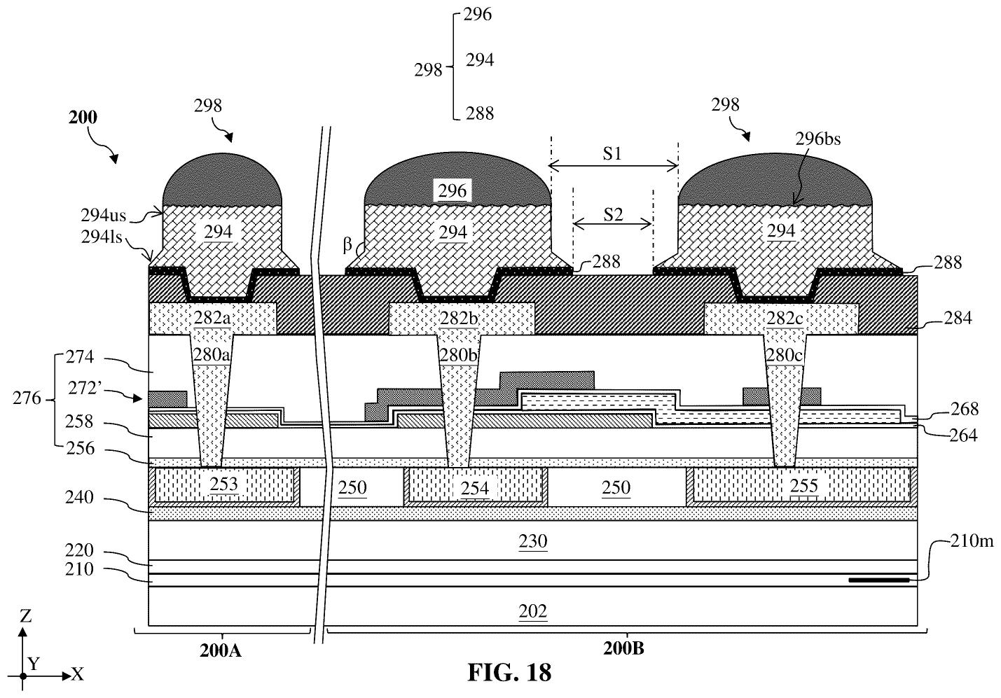

Referring to FIGS. 1 and 17-18, method 100 includes a block 124 where the patterned protective layer 290p is selectively removed and the UBM layer 288 is etched back. After the formation of the copper pillars 294 as well as the solder features 296, as represented in FIG. 17, the protective layer 290p is removed, for example, by ashing or selective etching. Reference is then made the FIG. 18. An etching process may be performed to selectively remove portions of the UBM layer 288 not covered by the copper pillars 294 as well as the solder features 296.

Referring to FIGS. 1 and 18, method 100 includes a block 126 where further processes are performed to finalize the fabrication process of the workpiece 200. For example, in an embodiment, a reflow process can be performed on the solder features 296, thus each of the solder features 296 becomes a reflowed solder feature with a spherical top surface as shown in FIG. 18. The solder feature 296, the metal pillar 294, and the UBM layer 288 thereunder form a bump structure 298. In the present embodiments, a sidewall surface of the copper pillar 294 includes a substantially vertical upper portion 294us and a slanted lower portion 2941s. The substantially vertical upper portion 294us and a slanted lower portion 2941s form an obtuse angle B. In the present embodiments, two adjacent solder features 296 are separated by a distance S1, and two adjacent UBM layers 288 are separated by a distance S2. The distance S2 is less than the distance S1. In an embodiment, a ratio of the distance S2 to the distance S1 may be in a range between about 0.5 and about 0.8. If the ratio is greater than 0.8, then, the stress may not be spread out efficiently. If the ratio is less than 0.5, the distance S2 between two adjacent UBM layers 288 may be too small, increasing the circuit short risk. In an embodiment, 10 μm≤S1≤130 μm, and 10 μm <S2<130 μm.

After forming the bump structure 298, the workpiece 200 may be attached to a substrate, such as a dielectric substrate, a package substrate, a printed circuit board (PCB), an interposer, a wafer, another chip, a package unit, or the like. For example, embodiments may be used in chip-to-substrate bonding configuration, a chip-to-chip bonding configuration, a chip-to-wafer bonding configuration, a wafer-to-wafer bonding configuration, chip-level packaging, wafer-level packaging, or the like. In an embodiment, the bump structure 298 may be connected to a metal trace formed in a semiconductor package.

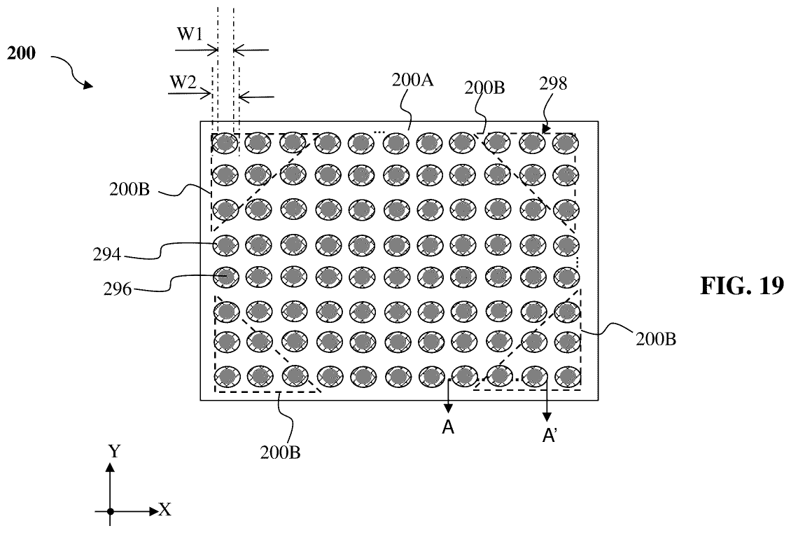

FIG. 19 depicts an exemplary top view of the workpiece 200 including the bump structures 298. In this depicted embodiment, the top view of the UBM layer 288 and/or the copper pillar 294 of the bump structure 298 is an oval shape, and the top view of the solder feature 296 is a round shape, and the top view of the workpiece 200 is a rectangle shape. It is understood that the top views of the copper pillar 294, the solder feature 296, and the workpiece 200 may have other shapes. In the present embodiments, the workpiece 200 include a corner region 200B and a non-corner region 200A, and all bump structures in the workpiece 200 have the same configuration (e.g., including the same copper pillar 294).

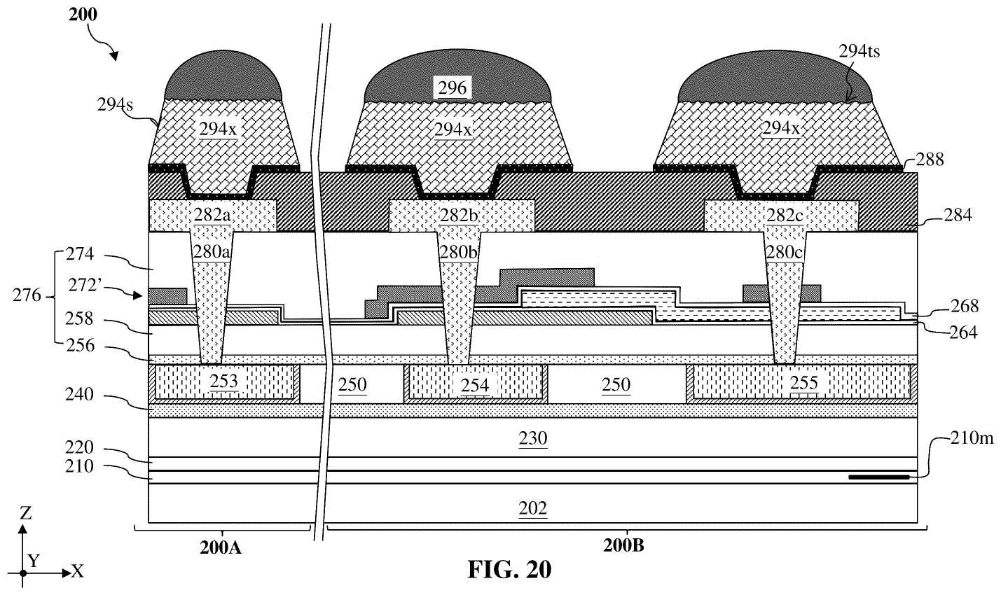

FIG. 20 depicts a first alternative workpiece, according to one or more embodiments of the present disclosure. The workpiece 200 depicted in FIG. 20 is similar to the workpiece 200 depicted in FIG. 18, and copper pillars 294x of the workpiece 200 depicted in FIG. 20 are similar to copper pillars 294 of the workpiece 200 depicted in FIG. 18. For example, the copper pillar 294x has more than 90% (111) crystal orientation and has the rough but planar top surface 294ts. One of the differences between the copper pillar 294 and copper pillar 294x includes that the profiles of the cross-sectional view of these two copper pillars are different. More specifically, in the above embodiments described with reference to FIG. 18, the copper pillar 294 has the middle portion 2942 having a non-uniform width bottom to top and the top portion 2943 having a substantially uniform width bottom to top. That is, in workpiece 200, the portion of the sidewall surface of the copper pillar 294 that is above the second passivation structure 284 has a tilted lower part and a substantially vertical upper part. In this alternative embodiment as represented in FIG. 20, the copper pillar 294x includes a lower portion (substantially same to the bottom portion 2941) extending into the second passivation structure 284 and an upper portion over the second passivation structure 284. The sidewall surface 294s of the upper portion of the copper pillar 294x is a slanted sidewall surface that tilts outward.

In embodiments described above with reference to FIGS. 1-20, all bump structures in the workpiece 200 have the textured copper pillar 294. In some alternative embodiments, different regions of a workpiece may have copper pillars with different configurations. FIG. 21 is a flow chart of a method 1000 for fabricating a semiconductor structure 200′, according to various aspects of the present disclosure. Method 1000 is described in conjunction with FIGS. 1-12 and FIGS. 22-27, which are fragmentary cross-sectional views of the semiconductor structure 200′ at different stages of fabrication according to embodiments of method 1000. Method 1000 includes blocks 102-116 of method 100 described above, and repeated description is omitted. With reference to FIGS. 21, 13, and 22, method 1000 also includes a block 1100 where the protective layer 290 is patterned to form the openings 292 exposing portions of the UBM layer 288 formed in the pad access openings (e.g., the pad access openings 286b, 286c) in the region 200B while covering portions of the UBM layer 288 formed in the pad access openings (such as the pad access opening 286a) in the region 200A. The patterned protective layer 290 may be referred to as the protective layer 290p′. The composition and formation of the protective layer 290p′ may be similar to those of the protective layer 290p and repeated description is omitted for reason of simplicity.

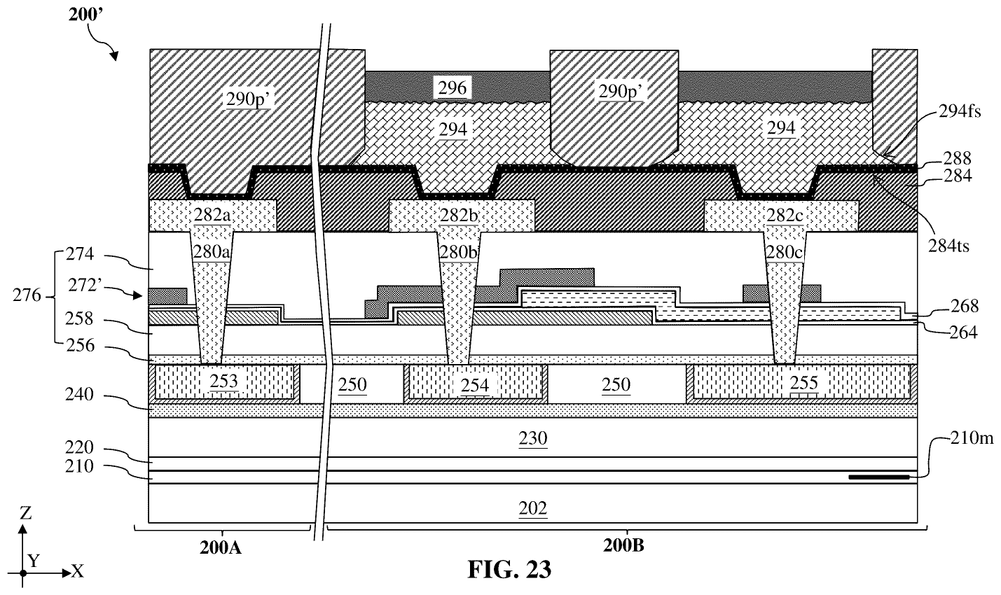

Referring to FIGS. 21 and 23, method 1000 includes a block 1200 where textured copper pillars 294 are formed in the region 200B. In the present embodiments, the textured copper pillars 294 may be referred to as first-type copper pillars 294. After forming the first-type copper pillars 294, solder features 296 are formed on the first-type copper pillars 294 and in the region 200B.

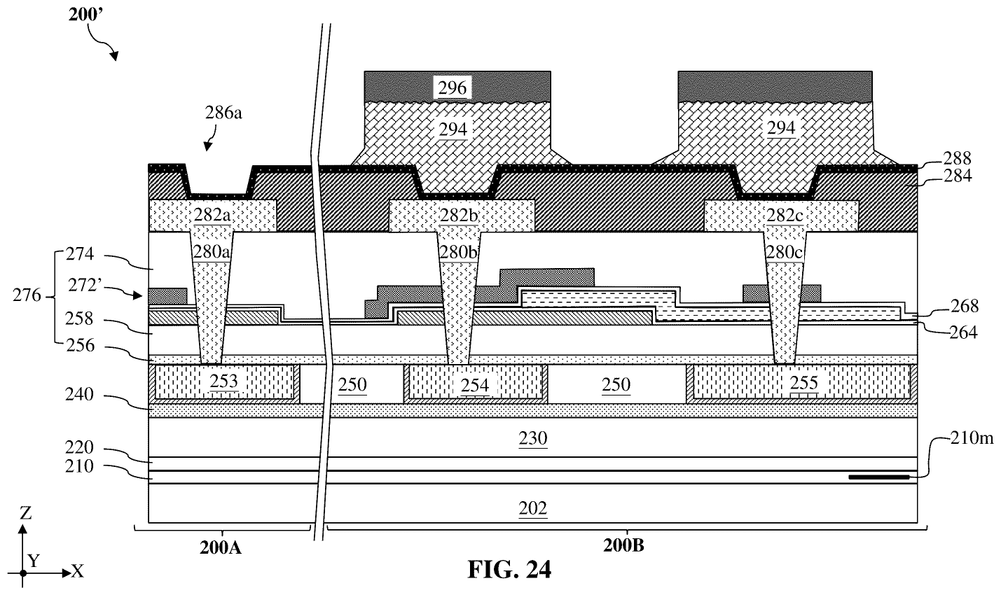

Referring to FIGS. 21 and 24, method 1000 includes a block 1300 where the protective layer 290p′ is selectively removed. After forming the first-type copper pillars 294 in the region 200B, the protective layer 290p′ is selectively removed, for example, by ashing or selective etching. The removal of the protective layer 290p′ releases the pad access openings (such as the pad access opening 286a) formed in the region 200A.

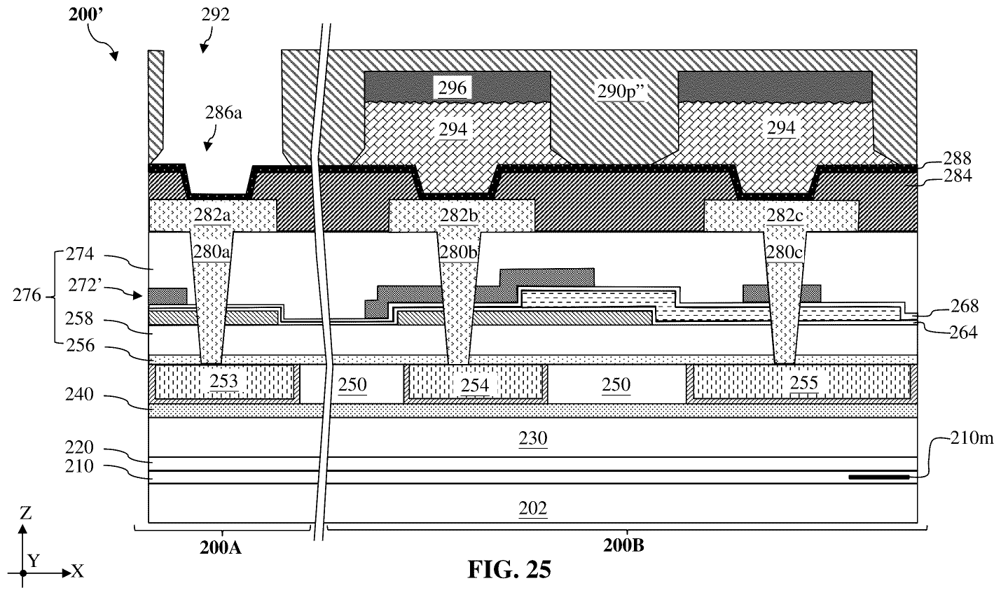

Referring to FIGS. 21 and 25, method 1000 includes a block 1400 where another patterned protective layer 290p″ is formed. The patterned protective layer 290p″ may be formed in a way similar to that of the protective layer 290p and is configured to expose portions of the UBM layer 288 formed in pad access openings (such as the pad access opening 286a) in the region 200A while covering features formed in the region 200B.

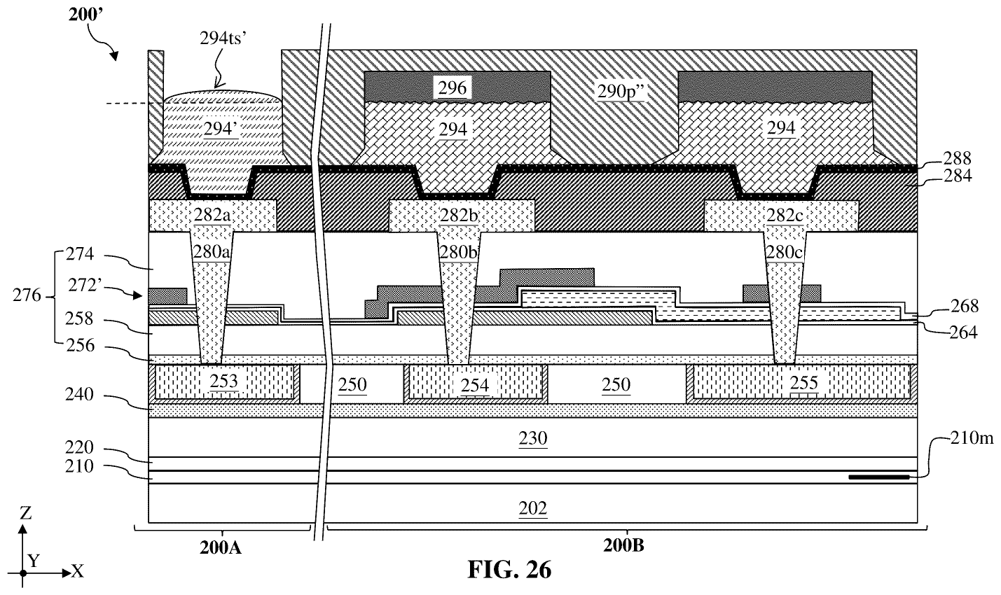

Referring to FIGS. 21 and 26, method 1000 includes a block 1500 where copper pillars 294′ formed of regular copper are formed in and over the pad access openings (such as the pad access opening 286a) in the region 200A. In the present embodiments, copper pillars 294′ formed of regular copper may be referred to as second-type copper pillars 294′. In an embodiment, the second-type copper pillar 294′″ has less than 30% (111) crystal orientation. The second-type copper pillar 294′ has a substantially smooth top surface 294ts′. That is, an average roughness of the top surface 294ts′ of the second-type copper pillar 294′ is less than that of the top surface 294ts of the first-type copper pillar 294. In addition, as depicted in FIG. 26, the top surface 294ts′ of the second-type copper pillar 294′ is a convex top surface. In an embodiment, a topmost point of the second-type copper pillar 294′ is above the top surface 294ts of the first-type copper pillar 294.

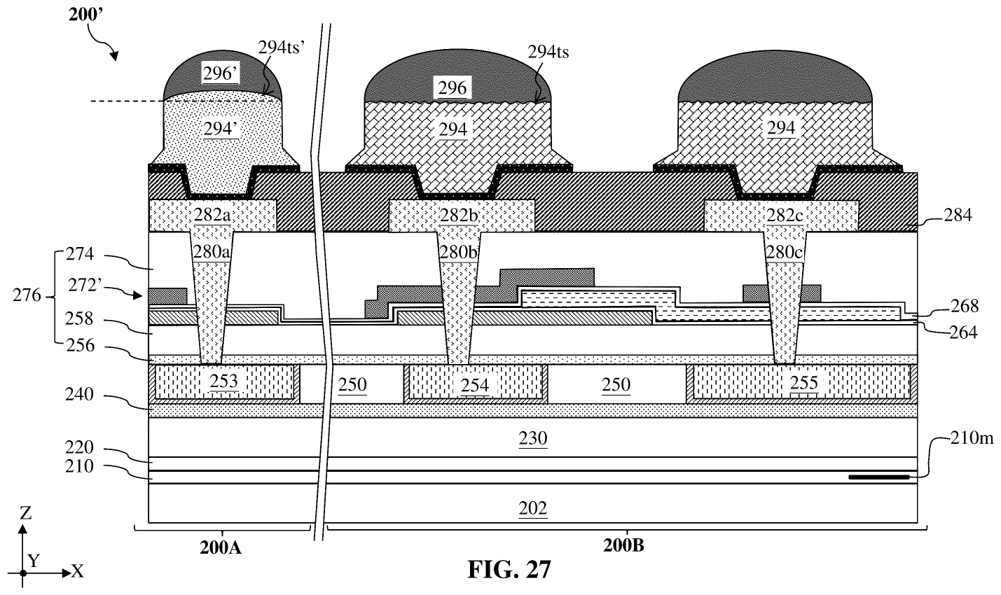

Referring to FIGS. 21 and 27, method 1000 includes a block 1600 where solder features 296′ are formed over the second-type copper pillars 294′, and the patterned protective layer 290p″ is selectively removed. In the present embodiment, the solder feature 296′ includes a smooth concave bottom surface in direct contact with the top surface 294ts′ of the second-type copper pillar 294′. After forming the second-type copper pillars 294′ in the region 200A and first-type copper pillars 294 in the region 200B, operations of block 126 of method 100 may be performed to finish the fabrication process. In some embodiments, the second-type copper pillars 294′ may be formed before forming the first-type copper pillars 294.

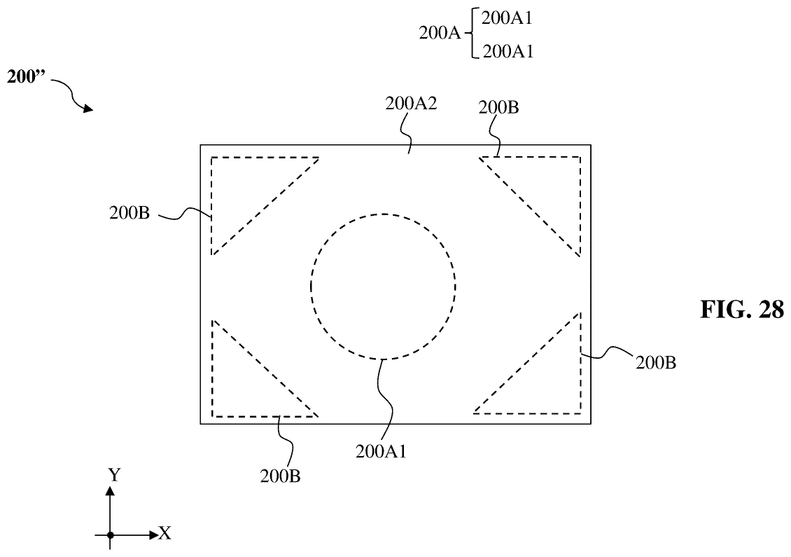

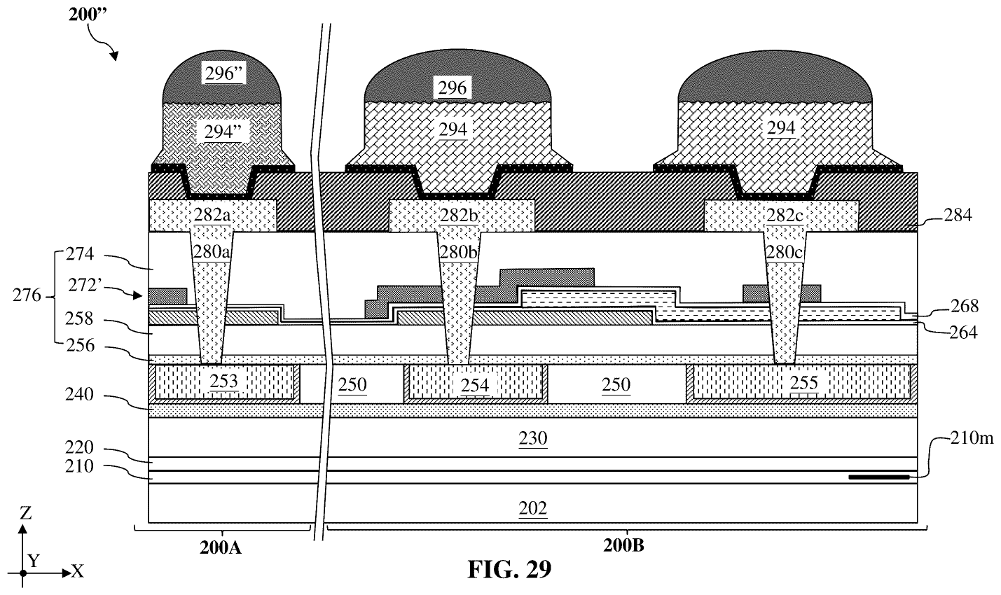

In embodiments described above with reference to FIGS. 21-27, all bump structures in the non-corner region 200A of the workpiece 200 have the second-type copper pillar 294′. In some alternative embodiments, different parts of the non-corner region 200A may have copper pillars with different configurations. FIG. 28 depicts a fragmentary top view of an alternative semiconductor structure 200″, according to various aspects of the present disclosure. The workpiece 200″ includes the corner region 200B and non-corner region 200A. The non-corner region 200A includes an inner part 200A1 and an outer part 200A2 surrounding the inner part 200A1. The inner part 200A1 may include bump structures having the second-type copper pillars 294′ and the corner region 200B may include bump structures having the first-type copper pillars 294. The outer part 200A2 may include bump structures having copper pillars 294″ (shown in FIG. 29). FIG. 29 depicts a cross-sectional view of the workpiece 200″ taken along line A-A′ shown in FIG. 28. In the present embodiments, the copper pillar 294″ may be similar to the copper pillar 294 but has a lower percentage of (111) crystal orientation. In an embodiment, the percentage of the (111) crystal orientation of the copper pillar 294″ is greater than that of the copper pillar 294′ and is less than that of the copper pillar 294. In an embodiment, the percentage of the (111) crystal orientation of the copper pillar 294″ may be between about 60% and about 80%. An average roughness (Ra) of the top surface of the copper pillar 294″ is greater than that of the copper pillar 294′ and is less than that of the copper pillar 294.

Although not intended to be limiting, one or more embodiments of the present disclosure provide many benefits to a semiconductor structure and the formation thereof. For example, the present disclosure provides metal bumps having textured copper pillars. In the present embodiments, inventors of the present disclosure found that a value of the Young's modulus of the textured copper pillars is less than that of the regular copper. Thus, metal bumps having textured copper pillars may withstand higher stress without excessive deformation. In some embodiments, the metal bumps have footing profiles to increase the contact area between the metal bumps and the passivation structure thereunder to further reduce stress buildup, and cracks that may be caused by the stress would be advantageously reduced, and the overall performance and reliability of the semiconductor structure and the IC chip may be improved.

The present disclosure provides for many different embodiments. Semiconductor structures and methods of fabrication thereof are disclosed herein. In one exemplary aspect, the present disclosure is directed to a semiconductor structure. The semiconductor structure includes a first contact pad over a substrate, a first under-bump metallization (UBM) layer over the first contact pad, a first metal pillar over first UBM layer and electrically coupled to the first contact pad via the first UBM layer, and a first solder cap on the first metal pillar, where the first metal pillar comprises copper, and a percentage of (111) crystal orientation of the copper is 90% or more.

In some embodiments, the first metal pillar may include a substantially planar top surface. In some embodiments, an average roughness of the substantially planar top surface of the first metal pillar may be between about 30 μm and about 130 μm. In some embodiments, the semiconductor structure may also include a second contact pad over the substrate, a second UBM layer over the second contact pad, a second metal pillar over the second contact pad and electrically coupled to the second contact pad via the second UBM layer, and a second solder cap on the second metal pillar, where the second metal pillar may include copper and has less (111) crystal orientation than the first metal pillar. In some embodiments, the second metal pillar may include a convex top surface. In some embodiments, an average roughness of the top surface of the second metal pillar may be less than an average roughness of a top surface of the first metal pillar. In some embodiments, the first solder cap is spaced apart from the second solder cap by a first distance, and the first UBM layer is spaced apart from the second UBM layer by a second distance, a ratio of the second distance to the first distance may be between about 0.5 and about 0.8. In some embodiments, the first metal pillar may include a lower sidewall surface and an upper sidewall surface, and the lower sidewall surface and the upper sidewall surface form an obtuse angle. In some embodiments, the lower sidewall surface may include a tilted sidewall surface. In some embodiments, the percentage of (111) crystal orientation of the copper may be no less than 97%.

In another exemplary aspect, the present disclosure is directed to a semiconductor structure. The semiconductor structure includes a first metal feature and a second metal feature in a dielectric layer, a passivation structure over the dielectric layer, a first contact pad over the passivation structure and electrically coupled to the first metal feature, a second contact pad over the passivation structure and electrically coupled to the second metal feature, a first copper pillar over and electrically coupled to the first contact pad, and a second copper pillar over and electrically coupled to the second contact pad, wherein the first copper pillar comprises a rough top surface.

In some embodiments, an average roughness of the top surface may be between about 30 μm and about 130 μm. In some embodiments, the top surface of the first copper pillar spans a width W1, and a bottom surface of the first copper pillar spans a width W2, the width W2 may be greater than the width W1. In some embodiments, the first copper pillar is an integral feature and comprises an upper portion having a uniform width bottom to top and a lower portion having a non-uniform width bottom to top. In some embodiments, the second copper pillar may include a rough top surface, and an average roughness of the top surface of the second copper pillar may be substantially equal to an average roughness of the top surface of the first copper pillar. In some embodiments, a top surface of the second copper pillar may be a substantially smooth convex top surface.

In yet another exemplary aspect, the present disclosure is directed to a method. The method includes forming a conductive pad over a substrate, depositing a dielectric layer over the conductive pad, patterning the dielectric layer to form a trench exposing a top surface of the conductive pad, forming an under-bump metallization (UBM) layer on the dielectric layer and in the trench, electroplating a copper pillar on the UBM layer and in the trench, wherein a percentage of (111) crystal orientation in the copper pillar is no less than 90%, and forming a solder cap on the copper pillar.

In some embodiments, the method may also include, after the forming of the UBM layer, forming a protective layer over the UBM layer, patterning the protective layer to form an opening exposing a portion of the UBM layer formed in the trench, wherein, a width of a top portion of the patterned protective layer is greater than a width of a bottom portion of the patterned protective layer, after the forming of the solder cap, selectively remove the patterned protective layer, and removing a portion of the UBM layer not disposed directly under the copper pillar. In some embodiments, the copper pillar may include a top surface having an average roughness in a range between 30 μm and 120 μm. In some embodiments, the copper pillar may include a lower portion having a non-uniform width W1 bottom to up and an upper portion having a uniform width W2 bottom to up, the width W1 may be no less than the width W2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first conductive pad and a second conductive pad over a first dielectric layer;
depositing a second dielectric layer over the first and second conductive pads; and
forming a first copper pillar extending into the second dielectric layer to couple to the first conductive pad and a second copper pillar extending into the second dielectric layer to couple to the second conductive pad,
wherein a top surface of the first copper pillar is a convex top surface, and a top surface of the second copper pillar is a substantially planar top surface.

2. The method of claim 1, wherein an average roughness of the top surface of the first copper pillar is less than an average roughness of the top surface of the second copper pillar.

3. The method of claim 1, wherein a percentage of (111) crystal orientation of copper in the first copper pillar is less than a percentage of (111) crystal orientation of copper in the second copper pillar.

4. The method of claim 3, wherein the percentage of (111) crystal orientation of copper in the second copper pillar is no less than 90%.

5. The method of claim 3, wherein the percentage of (111) crystal orientation of copper in the first copper pillar is no greater than 30%.

6. The method of claim 1, further comprising:
forming a first solder cap on the first copper pillar, and
forming a second solder cap on the second copper pillar.

7. The method of claim 6, further comprising:
forming a first under-bump metallization (UBM) layer disposed between the first conductive pad and the first copper pillar, wherein a portion of the first UBM layer extends on a top surface of the second dielectric layer; and
forming a second under-bump metallization (UBM) layer disposed between the second conductive pad and the second copper pillar, wherein a portion of the second UBM layer extends on a top surface of the second dielectric layer, and the first UBM layer and the second UBM layer are formed of a same composition and have a same thickness.

8. The method of claim 7, wherein a distance between the first UBM layer and the second UBM layer is less than a distance between the first solder cap and the second solder cap.

9. A method, comprising:
forming a first conductive pad and a second conductive pad over a dielectric layer;
forming a passivation structure covering the first conductive pad and the second conductive pad;
forming a first trench extending through the passivation structure to expose the first conductive pad and a second trench extending through the passivation structure to expose the second conductive pad;
forming a mask over the passivation structure and in the first and second trenches;
patterning the mask, wherein the patterned mask covers the second trench and comprises an opening exposing the first trench, wherein, a lower portion of the opening spans a first width, and an upper portion of the opening spans a second width less than the first width;
forming a first conductive pillar in the first trench and the opening;
after the forming of the first conductive pillar, selectively removing the patterned mask; and
forming a second conductive pillar in and over the second trench, wherein the second conductive pillar is spaced apart from the first conductive pillar.

10. The method of claim 9, wherein a top surface of the first conductive pillar is a substantially planar top surface, and a top surface of the second conductive pillar is a convex top surface.

11. The method of claim 9, wherein an average roughness of a top surface of the first conductive pillar is greater than an average roughness a of a top surface of the second conductive pillar.

12. The method of claim 9, wherein a percentage of (111) crystal orientation of copper in the first conductive pillar is greater than a percentage of (111) crystal orientation of copper in the second conductive pillar.

13. The method of claim 12, wherein the percentage of (111) crystal orientation of copper in the first conductive pillar is no less than 90%.

14. The method of claim 12, wherein the percentage of (111) crystal orientation of copper in the second conductive pillar is no greater than 30%.

15. The method of claim 9, further comprising:
after the forming of the first conductive pillar and before the selectively removing of the patterned mask, forming a solder feature on the first conductive pillar, wherein a top surface of the solder feature is below a top surface of the patterned mask.

16. A method, comprising:
forming a first conductive pad and a second conductive pad over a first dielectric layer;
depositing a second dielectric layer over the first and second conductive pads; and
forming a first copper pillar extending into the second dielectric layer to couple to the first conductive pad and a second copper pillar extending into the second dielectric layer to couple to the second conductive pad,
wherein a top surface of the first copper pillar is a substantially smooth top surface, and a top surface of the second copper pillar is a rough top surface.

17. The method of claim 16, wherein an average roughness of the top surface of the second copper pillar is between about 30 μm and about 130 μm.

18. The method of claim 16, wherein the second copper pillar comprises a lower portion embedded in the second dielectric layer and an upper portion over the second dielectric layer, and the upper portion of the second copper pillar comprises a first part and a second part over the first part, wherein the first part has a non-uniform width bottom to top, and the second part has a uniform width bottom to top.

19. The method of claim 18, wherein a width of the first part is greater than a width of the second part.

20. The method of claim 16, wherein a percentage of (111) crystal orientation of copper in the first copper pillar is less than a percentage of (111) crystal orientation of copper in the second copper pillar.
